(19) United States
(12) Patent Application Publication
(10) Pub. No.: US 2010/0189194 A1
(43) Pub. Date: Jul. 29, 2010

(54) FREQUENCY GENERATION CIRCUIT

(75) Inventors: Mark Dawkins, Oxfordshire (GB); Chung Kei Thomas Chan, Oxfordshire (GB)

Correspondence Address: CAESAR, RIVISE, BERNSTEIN,;COHEN & POKOTILOW, LTD., 11TH FLOOR, SEVEN PENN CENTER, 1635 MARKET STREET, PHILADELPHIA, PA, 19103-2212, US

(73) Assignee: FUTURE WAVES UK LIMITED, London (GB)

(21) Appl. No.: 12/161,514

(22) PCT Filed: Jan. 19, 2007
(86) PCT No.: PCT/GB2007/050029

§ 371 Date: Jul. 18, 2008

Related U.S. Application Data
(60) Provisional application No. 60/761,363, filed on Jan. 24, 2006.

(30) Foreign Application Priority Data
Mar. 3, 2006 (GB) 0604269.1

(51) Int. Cl. H04L 27/00; H03L 7/06

(52) U.S. Cl. 375/316; 327/156

(57) ABSTRACT

A frequency generation circuit comprises a crystal oscillator (10) for providing an input frequency, a phase-locked loop circuit (28), and a programmable frequency divider (42) for frequency dividing an output from the phase-locked loop circuit. The frequency generation circuit can generate a plurality of different output frequencies for supply to respective DAB and FM tuners (50, 60, 70). The frequency generation circuit can be used, together with a baseband circuit (14), in a radio receiver (1, 2). The same oscillator (10) and phase-locked loop circuit are used to drive the baseband circuit.

### FIELD OF THE INVENTION

The present invention relates to a frequency generation circuit and more particularly to a frequency generation circuit for generating multiple frequencies from a single input frequency.

### BACKGROUND TO THE INVENTION

Many electronic devices and systems have a requirement to receive and transmit radio signals over multiple frequency bands. For example, cellular telephones may need to receive and transmit over two or even three bands. In the case of a Digital Audio Broadcasting (DAB) radio receiver, it may be desirable to enable the receiver to receive radio signals on DAB band L (1452-1492 MHz) and on DAB band III (174-240 MHz), as well on the FM band (65.8-108 MHz) For each reception band, multiple crystal oscillators and/or Voltage Controlled Oscillators (VCOs) may be required to drive both the tuner part and the baseband part, which typically have modular designs even though they may be integrated onto the same silicon chip. Such receivers require a complex set of crystal oscillators, VCOs and clock frequencies to function correctly.

### SUMMARY OF THE INVENTION

It is an object of the present invention to reduce the number of crystal oscillators and/or VCOs required for a multi-band radio receiver. In particular, it is an object to provide a multi-band radio receiver and which utilises only a single crystal oscillator and a single VCO.

According to a first aspect of the present invention there is provided a frequency generation circuit comprising a phase-locked loop circuit for receiving an input frequency, and a programmable frequency divider for frequency dividing an output from the phase-locked loop circuit, the frequency generation circuit being configurable for generating a plurality of different output frequencies to supply a plurality of tuners.

A frequency generation circuit of the invention allows a plurality of different output frequencies to be generated from a single input frequency supplied to the phase-locked loop circuit. It is an advantage that a single crystal oscillator and phase-locked loop circuit generate the output frequencies.

Preferably, the plurality of different output frequencies are for supply to a plurality of tuners on a single chip. More preferably, part of the frequency generation circuit is provided on the same chip.

The frequency generation circuit may be configurable for generating one or more output frequencies to supply a DAB L-Band tuner, a DAB Band III tuner and an FM Mode II tuner.

Preferably, an output of the phase-locked loop circuit is coupled to a plurality of frequency dividers, the plurality of frequency dividers including the programmable frequency divider.

A radio receiver may comprise the frequency generation circuit and one or more tuners. Preferably, the tuners are provided on a single chip. More preferably, part of the frequency generation circuit is provided on the same chip.

The tuners may comprise one or more DAB band tuners. Preferably, the DAB band tuners comprise a DAB L-Band tuner and/or a DAB Band III tuner. The tuners may also comprise one or more FM band tuners.

Preferably, the radio receiver further comprises a DAB/FM baseband circuit. More preferably, the clock frequencies of the baseband circuit are provided by the crystal oscillator.

In an embodiment, the crystal oscillator is tuneable, and the baseband circuit has means for tuning the crystal oscillator.

According to a second aspect of the present invention, there is provided a radio receiver comprising at least one tuner, a baseband circuit, and a frequency generation circuit comprising a tuneable crystal oscillator, a phase-locked loop circuit, and a programmable frequency divider for frequency dividing an output from the phase-locked loop circuit, the frequency generation circuit being both configurable for generating a plurality of different output frequencies to supply the at least one tuner and for providing the clock frequency to the baseband circuit. Preferably, the baseband circuit comprises means to tune the tuneable crystal oscillator. It is an advantage that a single frequency generation circuit can be used to generate the output frequencies for the tuners, and the clock frequencies for the baseband circuit.

The at least one tuner may be provided on a single chip. Preferably, part of the frequency generation circuit is provided on the same chip.

The at least one tuner may comprise at least one DAB band tuners. Preferably, the at least one DAB band tuners comprises a DAB L-Band tuner and/or a DAB Band III tuner. The at least one tuner may also comprise at least one FM band tuner.

### BRIEF DESCRIPTION OF THE DRAWINGS

A preferred embodiment of the invention will now be described with reference to the following drawings in which:

FIG. 1 illustrates schematically a local oscillator generation circuit with frequency generation and baseband components;

FIG. 2 illustrates a DAB L-Band mode tuner;

FIG. 3 illustrates a DAB Band III mode tuner; and

FIG. 4 illustrates an FM Band II mode tuner;

### DETAILED DESCRIPTION OF CERTAIN EMBODIMENTS OF THE INVENTION

The invention will be described with reference to a frequency generation circuit intended for use in a radio receiver, although a frequency generation circuit of the invention is not in principle limited to this use.

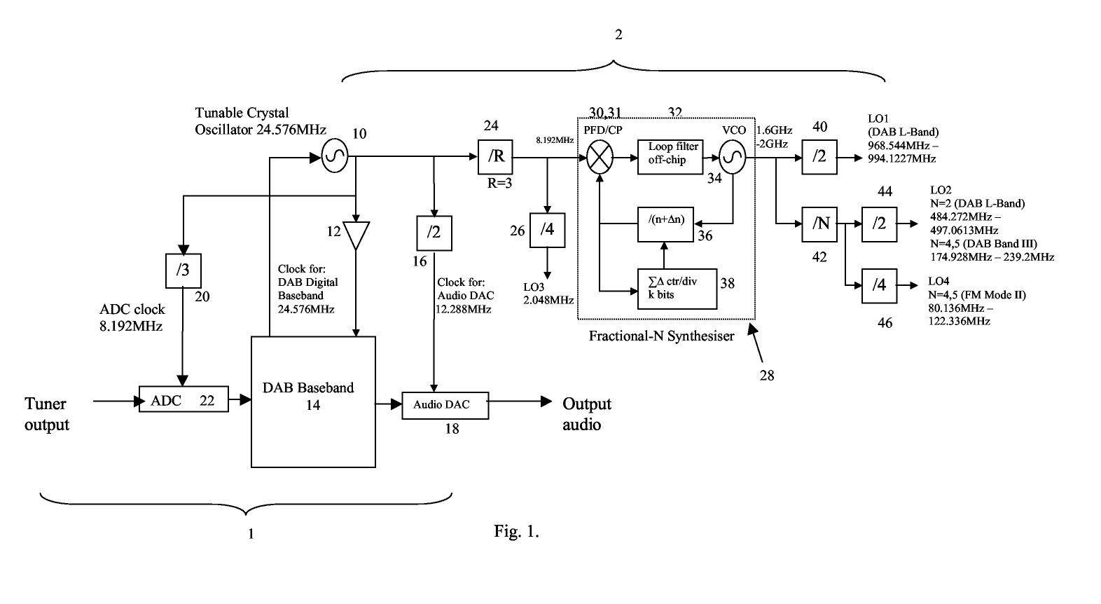

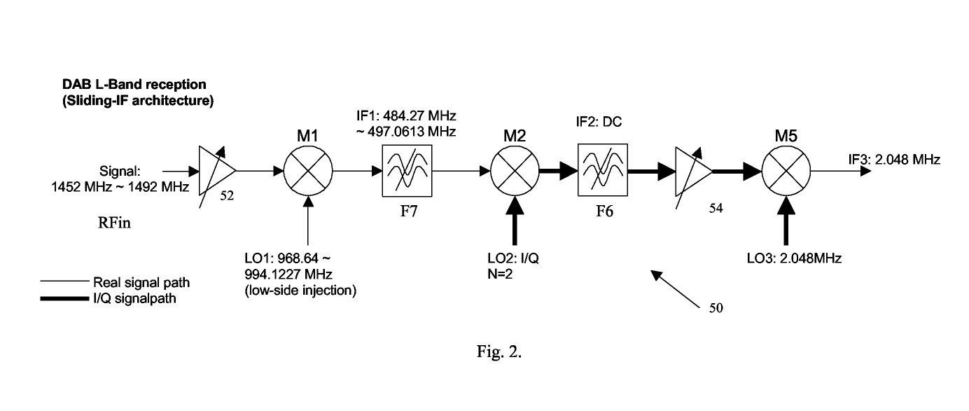

Referring to FIG. 1, a baseband circuit 1 and a frequency generation circuit 2 form part of a radio receiver. The receiver can receive radio signals at a plurality of different carrier frequencies, for example on DAB L-band mode, DAB Band III mode and FM Mode II. FIGS. 2, 3 and 4 show tuner circuits 50, 60, 70 of the receiver for each of these modes. The tuner circuits allow a user to tune to a desired frequency (channel) within each mode. The frequency generation circuit 2 is used to generate local oscillator frequencies LO1, LO2, LO3 and LO4, being different frequencies from one another, in order for the receiver to receive the DAB/FM bands. The local oscillator frequencies LO1, LO2, LO3, LO4 are fed into the tuner circuits 50, 60, 70 as tuning frequencies for the DAB L-band mode, DAB Band III mode and FM Mode II. This will be discussed in more detail below. Conveniently, the tuner circuits 50, 60, 70, and most of the components of the frequency generation circuit 2 can be provided on a single chip. Depending on the configuration of the baseband 1, it is possible to use the same baseband circuit 1 for both DAB and FM modes by using a DAB/FM baseband or DAB/FM demodulator/decoder circuit.

In order to generate the required frequency plan, a crystal oscillator 10 first generates an input signal. In the embodiment of FIG. 1, the crystal oscillator 10 generates an input signal at a frequency of 24.576 MHz. This signal is transmitted to a clock buffer 12, which drives the clock signal off chip to the baseband LSI (large scale integration), to provide a 24.576 MHz clock frequency for a baseband circuit 14. It is also transmitted to another buffer (not shown) and a frequency divider 16 to provide a clock frequency, for example a 12.288 MHz clock frequency if the frequency divider 16 divides the frequency by 2, for an audio digital to analog converter (DAC) 18, and to another buffer (not shown) and a frequency divider 20 to provide another clock frequency, for example an 8.192 MHz clock frequency if the frequency divider 20 divides the frequency by 3, for an analog to digital converter (ADC) 22. The audio DAC 18 produces a final audio output signal, enabling a user to listen to their chosen radio frequency that is being transmitted on the carrier signal.

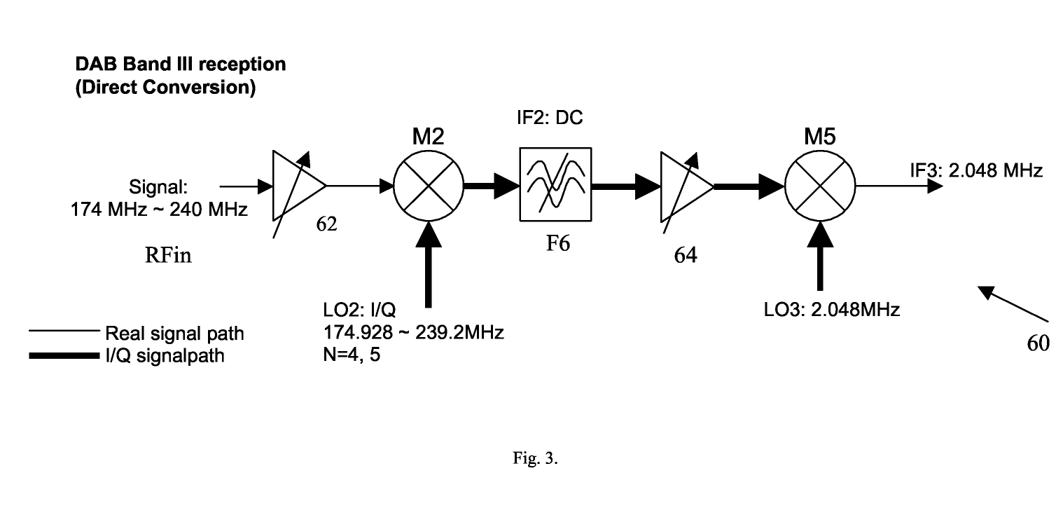

The signal from the oscillator 10 is also transmitted to a frequency divider circuit 24 which, for the specific embodiment described here, divides the signal frequency by three to produce a signal with a frequency of 8.192 MHz. This signal is further frequency-divided by another frequency divider 26 which, for the specific embodiment described here, divides the signal frequency by four to produce a local oscillator output frequency LO3 with a frequency of 2.048 MHz. The local oscillator frequency LO3 is used to generate the required 2.048 MHz output intermediate frequency (IF) for input to the ADC and baseband in DAB L-band mode and DAB Band III mode, as will be described later with reference to FIGS. 2 and 3.

The 8.192 MHz signal that is output from the divider 24 is also fed to a phase-locked loop (PLL) circuit 28. The PLL circuit 28 comprises a phase detector (PFD) 30 and a charge pump (CP) 31, a filter 32 and a voltage-controlled oscillator (VCO) 34. A frequency divider 36 and a clock-pulse counter 38 are also provided in the PLL circuit 28. The frequency divider 36 receives as its input an output from the voltage-controlled oscillator 34, and the output of the frequency divider 36 is provided as an input to the phase detector 30. In the preferred embodiment relating to a radio receiver, it is necessary for the PLL circuit 28 to output a signal with a frequency between about 1.6 and 2 GHz, the required frequency varying depending on whether DAB L-Band, DAB Band III or FM Mode II is required and upon the selected channel. (Details of the required frequency range of the output from the PLL circuit 28 are given, for one embodiment, in Table 1 below.) The frequency divider 36 and the clock-pulse counter 38 are configured to work together to enable the output signal from the voltage-controlled oscillator 34 to be frequency-divided by a varying amount n+Δn, where n is a whole number and Δn is an optional fractional amount. If Δn=0, the counter 38 is not needed and the frequency division is by the number n. If Δn is non-zero, the counter 38 is used in conjunction with the frequency divider 36 to effectively achieve fractional division.

The VCO 34 generates a periodic output signal with a frequency, in this embodiment, of between about 1.6 and 2 GHz. The phase detector 30 and the charge pump 31 are operable for slowing down or speeding up the oscillator 34, in order to phase-lock the output signal from the voltage-controlled oscillator 34 with the input signal from the crystal oscillator. The filter 32 is provided to generate a DC control voltage for the VCO 34 under the control of the charge pump. The output from the PLL circuit 28 is therefore stable and precisely defined.

According to the present invention, the signal output from the VCO 34 is supplied to a programmable frequency divider 42. A “programmable frequency divider”, as the term is used herein, denotes a frequency divider having a frequency division ratio that may be controlled (programmed) such that the frequency division ratio may be changed during operation. It is thus possible to obtain two or more output frequencies from the frequency generation circuit, by changing the frequency division ratio of the programmable frequency divider, even though the frequency generation circuit contains only a single crystal oscillator 10 and a single phase-locked loop circuit 28, by suitably changing the frequency division ratio of the programmable frequency divider 42.

The programmable frequency divider 42 may be implemented in any suitable manner. For example, the programmable frequency divider 42 may be implemented as a plurality of fixed-ratio frequency dividers that are switched on and off as necessary. The programmable frequency divider 42 may be implemented as described in co-pending UK patent application No. 0604263.4, the contents of which are hereby incorporated by reference.

In a particularly preferred embodiment, the output from the programmable frequency divider 42 is supplied to two (or more) frequency dividers having different frequency division ratios from one another. This further increases the number of output frequencies that may be obtained from the frequency generation circuit.

In the embodiment of FIG. 1, the signal output from the VCO 34 is supplied to a first frequency divider 40. The first frequency divider 40 divides the signal frequency by two, to produce a local oscillator frequency LO1 with a frequency in the range of 968.544 MHz-994.1227 MHz (for a VCO output with a frequency in the range of between about 1.94 and 2 GHz).

The 1.6 GHz-2 GHz output signal from the voltage-controlled oscillator 34 is also provided to the programmable frequency divider 42. The output signal from the programmable frequency divider 42 is transmitted to a second frequency divider 44 and to a third frequency divider 46. The programmable frequency divider 42 can divide the frequency of the signal by a number N, where may be controlled during operation to take one of two or more values. In this embodiment, the programmable frequency divider 42 may be controlled to divide the frequency of the signal by a number N, where N is 2, 4 or 5, with 50% duty cycle in each of the different modes.

A local oscillator frequency LO2 is produced by the second frequency divider 44, which takes as its input the output from the programmable frequency divider 42. In an embodiment in which the programmable frequency divider 42 frequency-divides by N=2 or N=4, 5, and in which the second frequency divider 44 frequency-divides by two, the second frequency divider may produce an output with a frequency range of 484.272 MHz-497.0613 MHz when the programmable frequency divider 42 frequency-divides by N=2, and may produce an output with a frequency range of 174.928 MHz-239.2 MHz when the programmable frequency divider 42 frequency-divides by N=4 or 5.

The local oscillator frequencies LO1 and LO2, and the local oscillator frequency LO3, are used as tuning frequencies in DAB L-band mode. The local oscillator frequency LO2 and the local oscillator frequency LO3 are used as tuning frequencies in DAB Band III.

A further local oscillator frequency LO4 is outputted from the third frequency divider 46, which takes as its input the output from the programmable frequency divider 42. In the embodiment of FIG. 1 in which the programmable frequency divider 42 frequency-divides by N where N=2 or N=4, 5, and in which the third frequency divider 46 frequency-divides by four, the third frequency divider 46 may, by arranging for the programmable frequency divider 42 to frequency-divide by N=4 or 5, produce an output with a frequency in the range 80.136 MHz-122.336 MHz. The local oscillator frequency LO4 is used as a tuning frequency in FM mode II.

Referring now to FIG. 2, the local oscillator frequencies LO1, LO2 and LO3 are fed into a DAB L-Band tuner 50, and mixed with an incoming signal (RFin) from the radio receiver's antenna. The tuner 50 produces an output signal IF3, which can be input to the ADC 22 of the baseband circuit 1.

FIG. 2 shows, from left to right, the signal path for the DAB L-Band tuning. The incoming radio signal RFin, which has a frequency of 1452-1492 MHz, is transmitted to a variable gain, low noise amplifier (LNA) 52. The signal is then transmitted to a mixer M1 together with the local oscillator frequency LO1. A sliding IF architecture, where the first IF at the output of the mixer M1 is not fixed but “slides” from ˜484-497 MHz, is used where the local oscillator frequency LO2 is equal to 1/N of the local oscillator frequency LO1 (that is, LO2=1/N LO1), where N=2 and the frequency of the signal Rfin is equal to (3/2) of the local oscillator frequency LO1 (that is f_{Rfin}=(3/2)LO1). The mixer M1 uses low side injection mixing to convert the input L-band (RFin) signal (˜1452-1492 MHz), via a filter F7, to a variable intermediate frequency (IF1) (˜483-497 MHz) using the lower frequency local oscillator frequency LO1. The IF1 signal is then fed into a second mixer M2, together with the local oscillator frequency LO2, and is converted to a second intermediate frequency IF2=0 Hz by the local oscillator frequency LO2. This baseband signal is then transmitted to a filter F6 and a variable gain amplifier 54. A further mixer M5 is provided to up-convert the signal to the output signal IF3 at 2.048 MHz, by feeding in the local oscillator frequency LO3. The required frequency range of the VCO is 1937.088-1988.2453 MHz.

Referring to FIG. 3, the LO2 and LO3 local oscillator frequencies are fed into a DAB Band III tuner 60, and mixed with an incoming signal RFin from the radio receiver's antenna. The tuner 60 produces an output signal IF3, at a frequency of 2.048 MHz, which can be input to the ADC 22 of the baseband circuit 1.

FIG. 3 shows, from left to right, the signal path for the DAB Band III tuning. The incoming signal RFin, which has a frequency within the range of 174-240 MHz, is transmitted to a variable gain LNA 62. The signal is then fed to a mixer M2, where it is mixed with the local oscillator frequency LO2, and directly converted (i.e. f_{RFin}=LO2 and N=4,5) to an intermediate frequency IF2. This baseband signal is then transmitted to a filter F6 and a variable gain amplifier 64. The required signal at 0 Hz is up-converted to IF3 2.048 MHz by mixing with the local oscillator frequency LO3 in the mixer M5. The required frequency range of the VCO is 1.608576-1.9936 GHz. The tuner 60 produces an output signal IF3, which can be input to the ADC 22 of the baseband circuit 1.

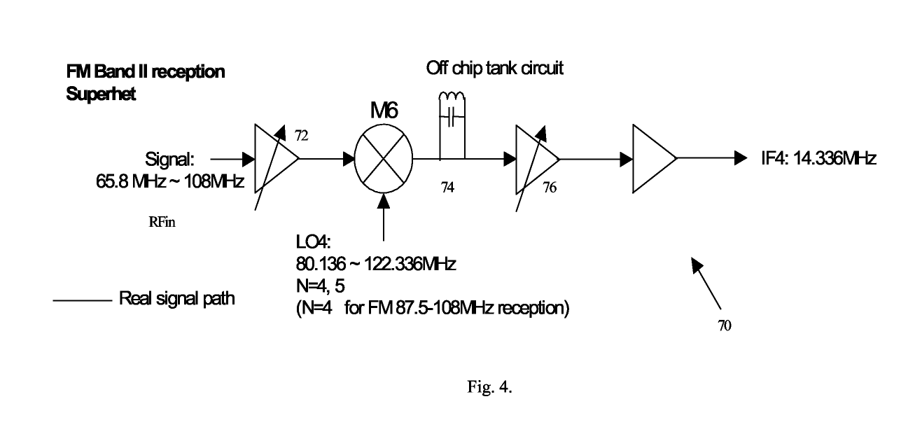

Referring to FIG. 4, the LO4 local oscillator frequency is fed into an FM Band II tuner 70, and mixed with the incoming signal RFin from the radio receiver's antenna. The tuner 70 produces an output signal IF4, at a frequency of 14.336 MHz, which can be input to the ADC 22 of the baseband circuit 1. The same baseband circuit 1 can be used as for DAB, if it also supports FM demodulation.

FIG. 4 shows, from left to right, the signal path for the FM Band II tuning. The FM tuner is a superheterodyne (superhet) tuner, with an IF output IF4 at 14.336 MHz. The incoming RFin signal is within the frequency range of 65.8-108 MHz. The RF signal is then fed, via a variable LNA 72, to a mixer M6. Here, the signal is mixed with the local oscillator frequency LO4 (N=4,5 in this case). The signal is then transmitted to an off-chip tank circuit, to filter out unwanted signals at frequencies which would alias into the wanted in the ADC 22, and then to another variable gain amplifier 76. The required frequency range of the VCO is 1629.376-1957.376 MHz

Each of FIGS. 2, 3 and 4 shows the real signal path and the I/Q signal path, the latter being represented by arrows in bold type.

The frequency generation for LO1, LO2, LO3 and LO4 are summarised in Table 1 below.

TABLE 1

| Signal | Modes | Local Oscillator Frequency | | VCO Frequency | |
|---|---|---|---|---|---|
| LO1 | DAB L-Band | 968.64-994.1227 | MHz | 1936-1989.333 | MHz |
| LO2 | N = 2 (DAB L-Band) | 484.272-497.0613 | MHz | 1936-1989.333 | MHz |
| | N = 4, 5 (DAB Band III) | 174.928-239.2 | MHz | 1.6-2 | GHz |
| LO3 | DAB L-Band, Band III | 2.048 | MHz | | |
| LO4 | N = 4, 5 (FM Mode II) | 80.136-122.336 | MHz | 1602.72-1957.376 | MHz |

The chosen frequency range of the output from the PLL circuit 28 is based on the target local oscillator frequencies and the practical divider ratios. In the embodiment of Table 1 the output from the PLL circuit 28 is required to cover at least the frequency range of 1.6-2 GHz, so that in this embodiment the frequency range of the PLL output is greater than necessary for some of the local oscillator frequencies (for example the local oscillator frequency LO1).

Embodiments of the present invention, as previously described, provide for a single crystal oscillator 10 and PLL circuit 28 to be used with multiple DAB and/or FM receivers. All of the necessary circuitry can be provided on a single chip, which can be used with existing DAB digital baseband LSIs but without the need for an expensive 38 MHz IF channel select SAW (surface acoustic wave) filter. The tuner circuitry, and the circuitry of the frequency generation circuit 2 (except for the crystal oscillator 10 and the PLL loop filter 32) can be provided on a single chip. Both of the DAB and FM IF outputs can be directly connected to an 8 bit ADC and sampled at 8.192 MHz. Furthermore, a single crystal oscillator 10 can be used to supply the signal to both the DAB baseband circuitry and the tuner circuitry.

It will be appreciated that the embodiments described herein are given by way of example only, and that various modifications may be made to these embodiments without departing from the scope of the present invention.

What is claimed is:

1. A frequency generation circuit comprising: a phase-locked loop circuit for receiving an input frequency and a programmable frequency divider for frequency dividing an output from the phase-locked loop circuit; the frequency generation circuit being configurable for generating a plurality of different output frequencies to supply a plurality of tuners.

2. The frequency generation circuit of claim 1, wherein the plurality of different output frequencies are for supply to a plurality of tuners on a single chip.

3. The frequency generation circuit of claim 2, wherein a part of the frequency generation circuit is provided on the chip.

4. The frequency generation circuit of claim 1, configurable for generating one or more output frequencies to supply a DAB L-Band tuner.

5. The frequency generation circuit of claim 1, configurable for generating one or more output frequencies to supply a DAB Band III tuner.

6. The frequency generation circuit of claim 1, configurable for generating one or more output frequencies to supply an FM Mode II tuner.

7. The frequency generation circuit of claim 1, wherein an output of the phase-locked loop circuit is coupled to a plurality of frequency dividers, the plurality of frequency dividers including the programmable frequency divider.

8. The frequency generation circuit of claim 1 further comprising a crystal oscillator for providing an input frequency to the phase-locked loop circuit.

9. A radio receiver comprising the frequency generation circuit of claim 1, and one or more tuners.

10. The radio receiver of claim 9, wherein the tuners are provided on a single chip.

11. The radio receiver of claim 10, wherein a part of the frequency generation circuit is also provided on the chip.

12. The radio receiver of claim 9, wherein the tuners comprise one or more DAB band tuners.

13. The radio receiver of claim 12, wherein the DAB band tuners comprise a DAB L-Band tuner and/or a DAB Band III tuner.

14. The radio receiver of claim 9, wherein the tuners also comprise one or more FM band tuners.

15. The radio receiver of claim 9, further comprising a DAB/FM baseband circuit.

16. The radio receiver of claim 15, wherein the clock frequencies of the baseband circuit are provided by the crystal oscillator.

17. The radio receiver of claim 16, wherein the crystal oscillator is tuneable, and the baseband circuit has means for tuning the crystal oscillator.

18. A radio receiver comprising at least one tuner, a baseband circuit, and a frequency generation circuit comprising a tuneable crystal oscillator, a phase-locked loop circuit, and a programmable frequency divider for frequency dividing an output from the phase-locked loop circuit, the frequency generation circuit being both configurable for generating a plurality of different output frequencies to supply the at least one tuner and for providing the clock frequency to the baseband circuit.

19. The radio receiver of claim 18, wherein the baseband circuit comprises means to tune the tuneable crystal oscillator.

20. The radio receiver of claim 18, wherein the at least one tuner is provided on a single chip.

21. The radio receiver of claim 20, wherein a part of the frequency generation circuit is also provided on the chip.

22. The radio receiver of claim 18, wherein the at least one tuner comprises at least one DAB band tuners.

23. The radio receiver of claim 22, wherein the at least one DAB band tuners comprise a DAB L-Band tuner and/or a DAB Band III tuner.

24. The radio receiver of claim 18, wherein the at least one tuner also comprises at least one FM band tuner.
